(19) United States
(12) Patent Application Publication
(10) Pub. No.: US 2014/0168623 A1
(43) Pub. Date: Jun. 19, 2014

(54) EXPOSURE APPARATUS, EXPOSURE METHOD, AND METHOD OF MANUFACTURING DEVICE

(71) Applicant: CANON KABUSHIKI KAISHA, Tokyo (JP)

(72) Inventors: Rika HOSHINO, Utsunomiya-shi (JP); Yuhei SUMIYOSHI, Utsunomiya-shi (JP)

(73) Assignee: CANON KABUSHIKI KAISHA, Tokyo (JP)

(21) Appl. No.: 14/132,811

(22) Filed: Dec. 18, 2013

(30) Foreign Application Priority Data
Dec. 18, 2012 (JP) 2012-276121

(51) Int. Cl. G03F 7/20

(52) U.S. Cl. CPC G03F 7/70191
USPC 355/67

(57) ABSTRACT

An exposure apparatus includes: an optical element positioned along an optical axis of a projection optical system and configured to include a surface having a rotationally asymmetric shape; a driving unit configured to drive the optical element with at least two degrees of freedom; and a control unit configured to control the drive with two degrees of freedom to correct an aberration having twofold symmetry in a direction represented by a linear sum of the aberration of components in two directions based on information showing a relationship between a driving amount with two degrees of freedom and the components of the aberration in the two directions, and an amount to be adjusted of each of the components of the aberration in the two directions.

### BACKGROUND OF THE INVENTION

1. Field of the Invention

The present invention relates to an exposure apparatus, an exposure method, and a method of manufacturing a device.

2. Description of the Related Art

A projection optical system of an exposure apparatus is required to have extremely excellent optical performance. Hence, various adjustment mechanisms of optical performances such as a magnification adjustment mechanism and a wavefront aberration adjustment mechanism have been added to the projection optical system so far. Adjustment of a rotationally asymmetric aberration, which remains in the projection optical system or occurs when using it, is also a problem. There are various types of rotationally asymmetric aberration, and a rotationally asymmetric aberration having twofold symmetry in particular tends to remain or occur in the projection optical system. Twofold symmetry refers to the property of overlapping an original pattern after a half rotation. Representative rotationally asymmetric aberrations having twofold symmetry are astigmatism, and a difference between longitudinal and lateral magnifications. In the case of the astigmatism, when a pupil coordinate of the projection optical system is represented as (r, θ) on a polar coordinate system, the wavefront aberration is represented in the form of r̂2×cos(2θ+φ) and has twofold symmetry with respect to the pupil coordinate.

In addition, in the case of C2Mag, a distortion (image shift) has twofold symmetry with respect to an image plane coordinate. Note that although the term “C2Mag” is used in this specification, this term means not only the magnification difference between the longitudinal direction and the lateral but also the magnification difference between two arbitrary, orthogonal directions.

In other words, C2mag is defined as anisotropic magnification having 2-fold rotational symmetry.
Furthermore, regarding the astigmatism, and C2mag, higher order (the order is high in the radial vector direction) aberrations may occur.

These astigmatism and difference between longitudinal and lateral magnifications may occur as a result of errors in the plane of a lens or a mirror which constitutes the projection optical system, and a residual error which cannot be adjusted completely upon assembly may remain in the projection optical system. The astigmatism and C2mag may also occur when the projection optical system absorbs exposure heat and warms up asymmetrically with respect to its optical axis. In this case, these aberrations continue to change in accordance with the absorbed exposure heat amount.

As a characteristic of an aberration having twofold symmetry, there are two types of fundamental aberration components, and an aberration in every direction can be represented by their linear combination. For example, when the wavefront aberration is astigmatism (AS), it has two fundamental components: ASc=r̂2×cos(2θ) and ASs=r̂2×sin(2θ), and the astigmatism AS in every direction can be represented as a linear combination of these components: AS=C1×ASc+C2×ASs.

On the other hand, in the case of C2mag, C2mag can be represented by a linear combination of two fundamental aberrations, that is, C2Mag in a 0° direction and that in a 45° direction. First of all, C2mag can be represented as:

dx=(M/2)(x cos 2θ+y sin 2θ)

dy=(M/2)(x sin 2θ−y cos 2θ) (1)

where dx represents the image shift amount in the X direction, dy represents the image shift amount in the Y direction, M represents the magnitude, and θ represents the direction.

When θ=0°, equation (1) is rewritten as equation (2) below. This case will be referred to as TY_{—}0 hereinafter (see FIGS. 3A and 3B).

dx=(M/2)x

dy=−(M/2)y (2)

Furthermore, when θ=45°, equation (1) is rewritten as to equation (3) below. This case will be referred to as TY_{—}45 hereinafter (see FIGS. 3C and 3D).

dx=(M/2)y

dy=(M/2)x (3)

By using these two components, TY_{—}0 and TY_{—}45, C2mag in every direction can also be represented by a linear combination of two performances of TY_{—}0 and TY_{—}45 for arbitrary θ in equation (1).

According to Japanese Patent No. 03341269, the rotationally asymmetric optical performance having twofold symmetry at a particular direction of the projection optical system is conventionally adjusted by providing two members with rotationally asymmetric shapes and changing the gap between the two members or relatively rotating the two members. Conventionally, the adjustment of an aberration component having twofold symmetry has been used for the purpose of compensating for an asymmetric expansion of a reticle in a projection optical system, or adapting to the deformation of an underlayer which has already been exposed in a step-and-scan exposure apparatus (a distortion, which is called a skew component and turns into a parallelogram is known to occur in a step-and-scan exposure apparatus). In those cases, only the TY_{—}0 component need be controlled in the former, and only the TY_{—}45 component need be controlled in the latter. Hence, an effect can be obtained to a certain degree as long as the projection optical system is equipped with a mechanism for controlling only the TY_{—}0 component or the TY_{—}45 component.

However, as the requirement for overlay accuracy increases, there is an increasing demand for controlling both the TY_{—}0 component and the TY_{—}45 component. Particularly in recent years, the exposure apparatus has been required to perform exposure in accordance with a distorted shot within a distorted wafer along with the proliferation of a chip laminating technique such as TSV (Through-silicon via) or a back-side illumination CMOS sensor. Note that TSV is a mounting technology using a silicon feedthrough electrode. Distortion of the wafer is not a unique phenomenon and has a different magnitude and direction for each location. Therefore, in order to adapt to the distortion of the wafer, the exposure needs to be performed with changing the magnitude and the direction of C2mag of the projection optical system for each shot. In order to achieve this, the projection optical system needs to mount a mechanism, which is capable of controlling both the TY_{—}0 component and the TY_{—}45 component.

In a method described in Japanese Patent No. 03341269, it was required to position two units for controlling C2mag in one direction to form an angle of 45° each other or to make the entire unit for controlling C2mag in one direction rotatable in order to control both the TY_{—}0 component and the TY_{—}45 component. However, positioning two units for controlling C2mag in one direction to form an angle of 45° is difficult in terms of space. In general, because the projection optical system is required to have extremely high optical performance, lenses are densely packed from the object plane to the image plane without any gaps to correct aberrations, and lens barrel components for holding them are arranged without any gaps. Securing a space for positioning both a rotationally asymmetric member and a mechanism for precisely controlling it in the optical path of a projection optical system may be possible if only for one set, but is difficult for two or more sets in terms of design.

Furthermore, it is also difficult to make the entire unit for controlling C2mag in one direction rotatable in terms of driving accuracy. In the case of a mechanism for controlling C2mag by changing the gap between the two members, the gap between the two members is changed very precisely so as not to change anything other than the gap (such as movement or a tilt in a direction perpendicular to the optical axis or the like) in order not to influence other optical performances. Hence, the range of the change (stroke) in the gap between the two members is naturally limited to the range between several hundreds μm and several mm. The same goes for a mechanism for controlling C2mag by rotating the members, and the stroke of a rotation angle is limited from several minutes to several degrees. However, when rotating the entire unit in order to control the direction in which C2mag occurs, that range must cover every direction in 360 degrees. Rotating the unit in such a broad range freely as well as precisely without any axis shift or tilt is extremely difficult because of its mechanical structure. Moreover, the need for driving between the shots at a high speed makes it even more difficult.

Furthermore, whereas a method of correcting two different aberrations using the drive of one member has been examined, a method of correcting independent components of one aberration in an arbitrary direction by driving one member has not been examined.

### SUMMARY OF THE INVENTION

The present invention provides an exposure apparatus which controls one aberration having twofold symmetry with regard to an arbitrary direction by driving one member.

The present invention in its one aspect provides an exposure apparatus of projecting a pattern of a reticle on a substrate via a projection optical system and exposing the substrate to light, the apparatus comprising: an optical element positioned along an optical axis of the projection optical system and configured to include a surface having a rotationally asymmetric shape; a driving unit configured to drive the optical element with at least two degrees of freedom; and a control unit configured to control the drive with two degrees of freedom to correct an aberration having twofold symmetry in a direction represented by a linear sum of the aberration of components in two directions based on information showing a relationship between a driving amount with two degrees of freedom and the components of the aberration in the two directions, and an amount to be adjusted of each of the components of the aberration in the two directions.

Further features of the present invention will become apparent from the following description of exemplary embodiments with reference to the attached drawings.

### BRIEF DESCRIPTION OF THE DRAWINGS

FIG. 1 is a diagram showing an exposure apparatus according to the first embodiment;

FIG. 2 is a diagram showing an example of a set of two optical elements for adjusting an aberration;

FIGS. 3A to 3D are diagrams showing an image shift aberration due to a difference between longitudinal and lateral magnifications;

FIGS. 4A to 4C are diagrams showing an example of the surface shapes of the optical element;

FIG. 5 is a flowchart of an exposure method;

FIGS. 6A to 6C are diagrams showing another example of the set of the optical elements;

FIGS. 7A to 7C are diagrams showing still another example of the set of the optical elements; and

FIG. 8 is a diagram showing a projection optical system according to the second embodiment.

### DESCRIPTION OF THE EMBODIMENTS

Embodiments of the present invention will now be described in detail with reference to the accompanying drawings. Note that the present invention is not limited to the following embodiments, which are merely concrete examples advantageous for practice of the present invention. In addition, not all combinations of features described in the following embodiments are essential for the solution to the problem in the present invention.

### First Embodiment

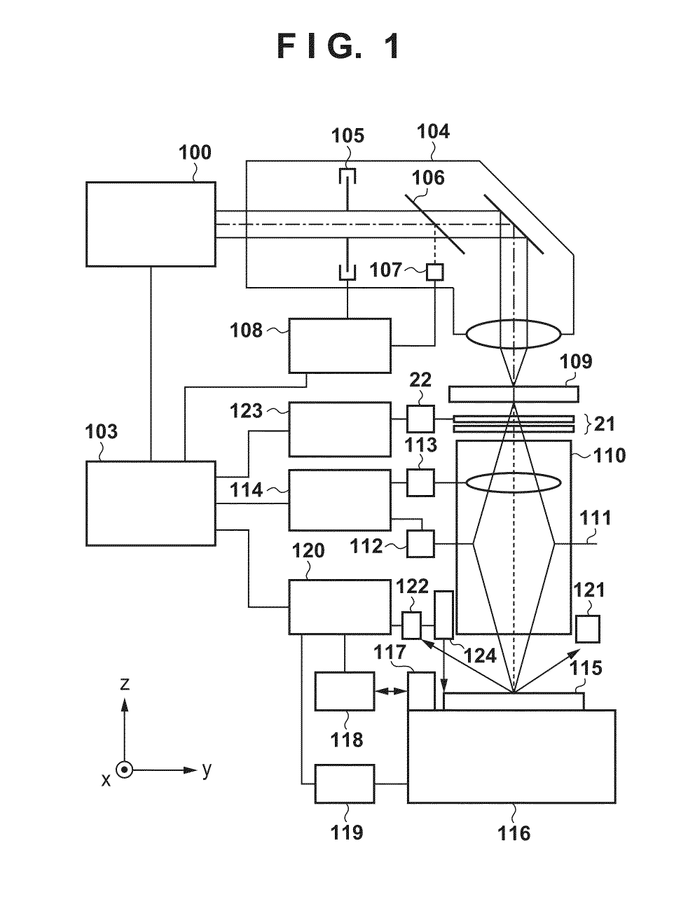

FIG. 1 shows an exposure apparatus according to the first embodiment. A light source 101 can output light in a plurality of wavelength bands as exposure light. The light emitted by the light source 101 is shaped into a predetermined shape through a shape optical system (not shown) of an illumination optical system 104. The shaped light is incident on an optical integrator (not shown) where a number of secondary light sources are formed to illuminate a reticle 109 to be described later with a uniform illuminance distribution.

The shape of an aperture portion of an aperture stop 105 in the illumination optical system 104 is almost circular, and an illumination optical system control unit 108 can set the diameter of its aperture portion and the numerical aperture (NA) of the illumination optical system 104 to desired values. In this case, since the value of the ratio of the numerical aperture of the illumination optical system 104 of that of a projection optical system 110 is a coherence factor (σ value), the illumination optical control unit 108 can set the σ value by controlling the aperture stop 105 of the illumination optical system 104.

A half mirror 106 is positioned in the optical path of the illumination optical system 104, and a part of the exposure light for illuminating the reticle 109 is reflected and extracted by this half mirror 106. An ultraviolet photosensor 107 is positioned in the optical path of the reflected light by the half mirror 106 and generates an output corresponding to the intensity (the exposure energy) of the exposure light. The pattern on a circuit of a semiconductor device to be printed is formed on the reticle (mask) 109 as an original and illuminated by the illumination optical system 104. The projection optical system 110 reduces the pattern on the reticle 109 to a reduction magnification β (for example, β=½), and is positioned to project one shot region on a wafer (substrate) 115 on which a photoresist is coated. The projection optical system 110 can be an optical system of a refractive type, a catadioptric system, or the like.

An aperture stop 111 whose aperture portion is almost circular is positioned on the pupil plane (a Fourier transform plane for the reticle) of the projection optical system 110, and the diameter of the aperture portion can be controlled by an aperture stop driving unit 112 such as a motor. An optical element driving unit 113 moves an optical element, which constitutes a part of a lens system in the projection optical system 110 such as a field lens, along the optical axis of the projection optical system 110. This keeps the projection magnification at a satisfactory value to reduce a distortion error while preventing various aberrations of the projection optical system 110 from deteriorating. A projection optical system control unit 114 controls the aperture stop driving unit 112 and the optical element driving unit 113 under the control of a main control unit 103.

A wafer stage (substrate stage) 116 for holding a wafer 115 is movable in three-dimensional directions, and can move in the direction of the optical axis (the Z direction) of the projection optical system 110 and within a plane (X-Y plane) perpendicular to the direction of the optical axis. Note that in FIG. 1, the direction, which is parallel to the optical axis of the projection optical system 110 and extends from the wafer 115 to the reticle 109, is defined as a Z-axis, and directions orthogonal to each other on a plane perpendicular to the Z-axis are defined as an X-axis and a Y-axis. Therefore, the Y-axis is within a paper surface, and the X-axis is perpendicular to and is directed to come out of the paper surface. A laser interferometer 118 measures the distance to a moving mirror 117 fixed to the wafer stage 116, thereby detecting the position of the wafer stage 116 on the X-Y plane. Also, positional shifts of the wafer 115 and the wafer stage 116 are measured using an alignment measurement system 124. A stage control unit 120 is under the control of the main control unit 103 of the exposure apparatus and moves the wafer stage 116 to the predetermined position on the X-Y plane by controlling a stage driving unit 119 such as the motor based on said measurement result.

A projection optical system 121 and a detection optical system 122 detect a focal plane. The light projection optical system 121 projects a plurality of light beams formed by non-exposure light to which the photoresist on the substrate 115 is not sensitive, and each light beam is focused on and reflected by the wafer 115. The light beam reflected by the wafer 115 is incident on the detection optical system 122. Although illustration is omitted, a plurality of light-receiving elements for position detection are positioned in correspondence with the respective reflected light beams within the detection optical system 122, and the detection optical system 122 is configured so that the light-receiving surface of each position detection light-receiving element is nearly conjugate with the reflection point of each light beam on the wafer 115 by an imaging optical system. The positional shift of the surface of the wafer 115 in the optical axis direction of the projection optical system 110 is measured as that of light incident on the light-receiving elements for position detection within the detection optical system 122.

As shown in FIG. 1, the projection optical system 110 includes an aberration adjustment member 21 for adjusting the aberration, which is made of a pair of optical elements 211 and 212 facing the reticle 109. The two optical elements (first optical element and second optical element) 211 and 212 are positioned via a gap along the optical axis of the projection optical system 110. The two optical elements (first optical element and second optical element) 211 and 212 have surfaces with the same rotationally asymmetric shape on the side of the gap, respectively. At least one of the two optical elements (first optical element and second optical element) 211 and 212 is driven with at least two degrees of freedom by an optical element driving unit 22. The drive with at least two degrees of freedom by the optical element driving unit 22 is controlled by an optical element control unit (control unit) 123. Note that in this embodiment, the aberration adjustment member 21 is made up of the pair of the optical elements 211 and 212, but only one of the two optical elements (first optical element and second optical element) 211 and 212 may be used.

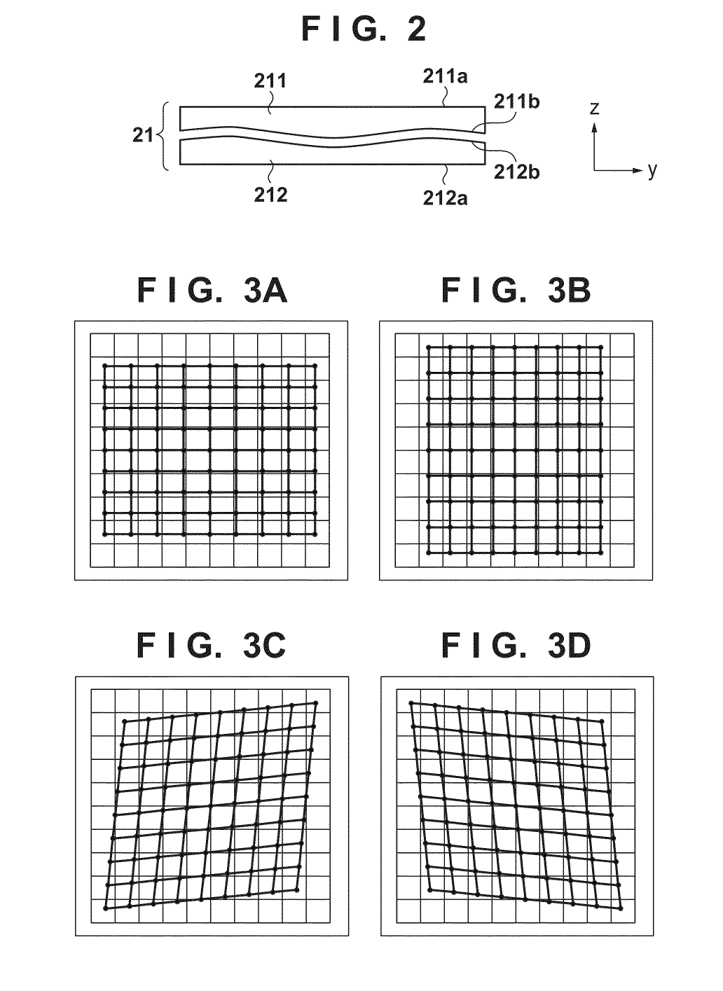

The configuration of the aberration adjustment member 21 in FIG. 1 will be described in detail. The aberration adjustment member 21 may be configured as a part of the projection optical system 110 or a separate unit from the projection optical system 110. In addition, the aberration adjustment member 21 may be integrated with a reticle holder or a reticle stage mechanism (not shown) for holding the reticle 109. In FIG. 2, the two optical elements 211 and 212 have outer surfaces 211a and 212a with planar shapes, and inner surfaces 211b and 212b facing each other with aspherical shapes in a complementary relationship with each other.

### Example 1

FIG. 2 shows the aberration adjustment member 21 in Example 1 for adjusting the aberration having twofold symmetry. In Example 1, the drive of the optical element 211 with two degrees of freedom is translation toward two directions. The inner surfaces 211b and 212b of the two optical elements 211 and 212 which have a rotationally asymmetric shape and face each other are represented, for example, by:

z=Ax³+B(x+y)³ (4)

where A and B are constants.

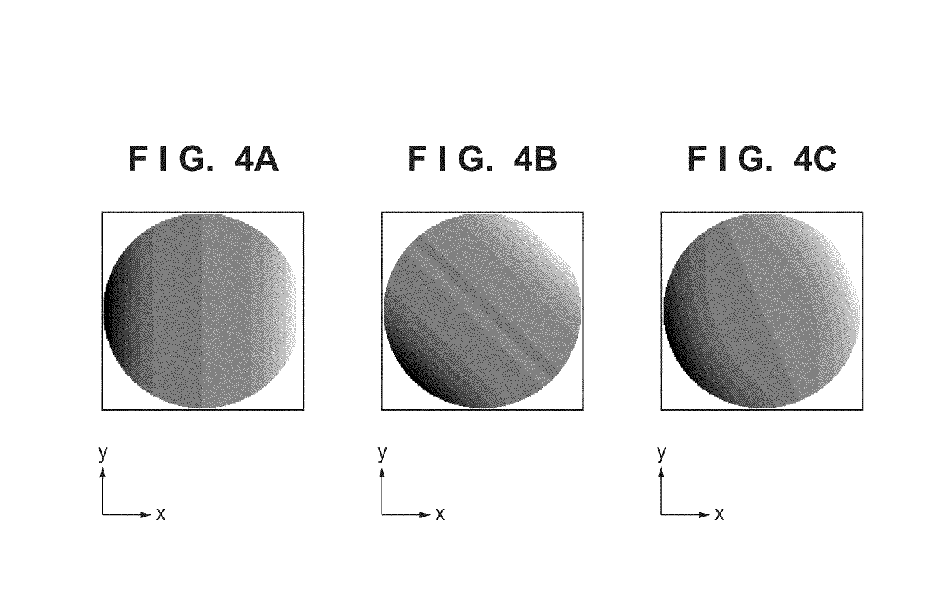

The rotationally asymmetric shape represented by equation (4) is a shape shown in FIG. 4C, which is a sum of a third-order shape toward a θ=0° (the X-axis) direction as shown in FIG. 4A, and a third-order shape toward a θ=45° direction, as shown in FIG. 4B. The drive of the optical element 211 with two degrees of freedom in this case is a drive along a Y-axis direction and a drive along a direction forming an angle of 135° from the X-axis on an X-Y plane.

The distortion of the TY_{—}0 component shown in FIGS. 3A and 3B occurs by driving the optical element 211 along the direction forming an angle of 135° from the X-axis by the optical element driving unit 22. Furthermore, the distortion of the TY_{—}45 component shown in FIGS. 3C and 3D occurs by driving the optical element 211 along the Y-axis direction. Hence, it is possible to control the components in two directions so as to create an aberration in a direction represented by a linear sum of the aberrations of the components in the two directions, that is, an arbitrary direction by controlling the a driving amount of the optical element 211 with two degrees of freedom on a plane defined by the Y direction and a direction forming an angle of 135° with the X-axis.

Moreover, the surface of the aberration adjustment member 21 with a rotationally asymmetric shape has may, for example, be a shape represented by:

z=Ar³ cos 3θ or

z=Br3 sin 3θ (5)

where r and θ are variables, and A and B are constants.

In this case, the two directions in which the optical element 211 is driven are set to be two directions of the X-axis direction and the Y-axis direction. Therefore, by driving the one optical element 211 in an arbitrary direction on the plane defined by the X-axis direction and the Y-axis direction, C2mag can be controlled with regard to an arbitrary direction.

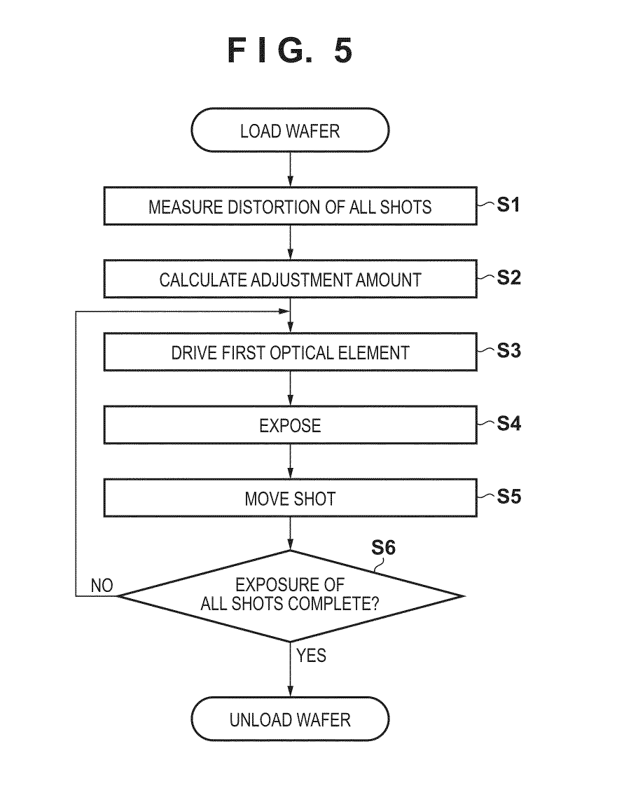

An example of an exposure method using the aberration adjustment member 21 for adjusting an aberration having twofold symmetry will now be described with reference to FIG. 5. As shown in FIG. 5, after loading the wafer, in step S1 the main control unit 103 measures the shape of a plurality of shot regions as an underlayer using the alignment measurement system (measurement device) 124, and stores the distortion of its all shots as data.

In step S2, the main control unit 103 calculates an amount to be adjusted (adjustment amount) of the components (the TY_{—}0 component and the TY_{—}45 component) of the aberration in the two directions for exposure in accordance with the shape of each shot region. The main control unit 103 may also calculate the adjustment amounts of other image shift components. In step S3, the optical element control unit 123 obtains the driving amount with two degrees of freedom based on the information showing the relationship between the driving amount with two degrees of freedom and the components of the aberration in the two directions, and the adjustment amounts of the components of the aberration in the two directions. The optical element control unit 123 drives the optical element 211 by the optical element driving unit 22 to adjust the TY_{—}0 component and the TY_{—}45 component based on the obtained driving amount with two degrees of freedom. At this time, in order to further adjust other image shift components, simultaneous driving may be performed for the optical element of the projection optical system 110 by the optical element driving unit 113 via the projection optical system control unit 114 and the wafer stage 116 by the stage driving unit 119 via the stage control unit 120. Upon completion of driving the optical element 211, the main control unit 103 performs an exposure in step S4.

In step S5, the main control unit 103 drives the wafer stage 116 so as to move the shot to be exposed next. The main control unit 103 continues to drive the optical element 211 and to perform exposure based on the results of the measurement of the distortion of the shot regions and the calculation of the adjustment amount executed in advance in steps S1 and S2. After completion of exposing all shot regions is confirmed in step S6, the main control unit 103 unloads the wafer, and then loads a next wafer to repeat the flow shown in FIG. 5.

In the exposure method based on this flow, the exposure can be performed in accordance with a shot shape adapted to a shot distortion to be the underlayer by correcting C2mag having twofold symmetry with regard to an arbitrary direction, and thus overlay accuracy increases.

### Example 2

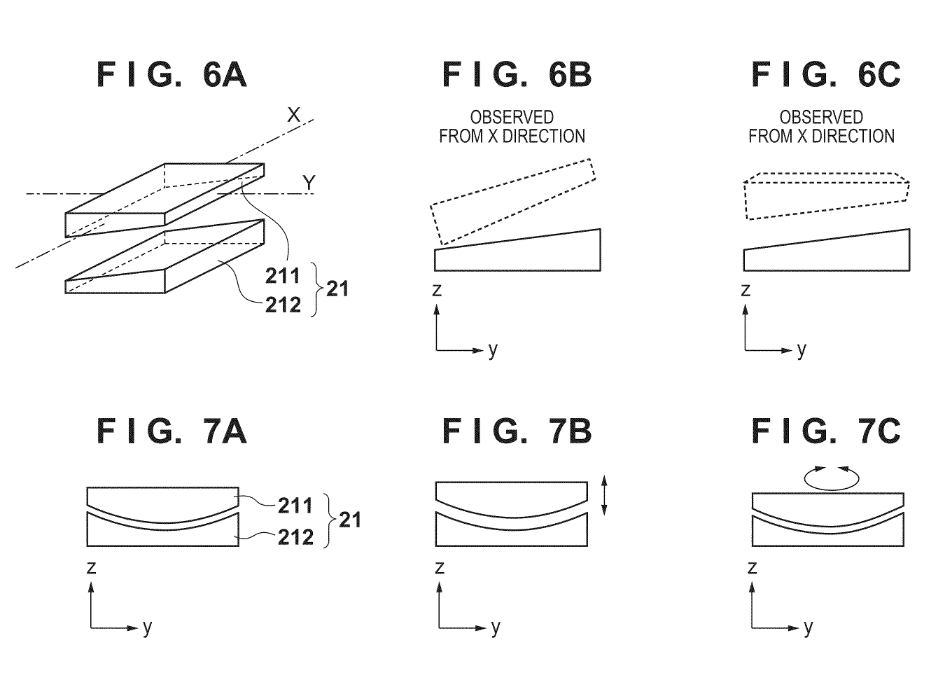

The aberration adjustment member 21 in Example 2 for adjusting an aberration having twofold symmetry will be described with reference to FIGS. 6A to 6C. In Example 2, the drive of the optical element 211 with two degrees of freedom is rotational drive about the X-axis (in a ωX direction) and about the Y-axis (in a ωY direction). As seen in FIG. 6A, the surface of the aberration adjustment member 21 with a rotationally asymmetric shape in Example 2 is so-called a wedge-shape, which is a plane in which the projection on a Y-Z plane is represented by a straight line inclined with respect to the Y-axis.

The distortion of the TY_{—}0 component shown in FIGS. 3A and 3B occurs by rotational driving of the optical element 211 about the X-axis as a rotation axis, as shown in FIG. 6B. Furthermore, the distortion of the TY_{—}45 component shown in FIGS. 3C and 3D occurs by rotational driving of the optical element 211 about the Y-axis as a rotation axis, as shown in FIG. 6C.

Hence, a difference between longitudinal and lateral magnifications can be created and controlled with regard to an arbitrary direction by rotational driving of the optical element 211 in an arbitrary direction about the intersection of the plane with the wedge and the Z-axis. It is also possible to use this aberration adjustment member 21 to control the rotationally asymmetric difference between longitudinal and lateral magnifications having twofold symmetry with regard to an arbitrary direction, and perform exposure in the same manner as in Example 1.

### Example 3

The aberration adjustment member 21 in Example 3 for adjusting the aberration having twofold symmetry will be described with reference to FIGS. 7A to 7C. In Example 3, the drive of the optical element 211 with two degrees of freedom is the translation toward the Z direction and the rotational drive about the Z-axis (in a ωZ direction). The surface of the rotationally asymmetric shape of the aberration adjustment member 21 in Example 3 is a cylinder surface, that is, a cylindrical surface in the Y-axis direction such as shown in FIG. 7A. Note that the surface of the rotationally asymmetric shape may be a surface represented by Ar² cos 2θ or Br² sin 2θ, where r and θ are variables, and A and B are constants, instead of the cylindrical surface.

The distortion of the TY_{—}0 component shown in FIGS. 3A and 3B occurs by driving the optical element 211 along the optical axis (Z-axis), as shown in FIG. 7B. Furthermore, the distortion of the TY_{—}45 component shown in FIGS. 3C and 3D occurs by rotational driving the optical element 211 in the ωZ direction about the optical axis, as shown in FIG. 7C. Hence, C2mag can be created and controlled with regard to an arbitrary direction by combining the drive of the optical element 211 toward the Z-axis direction and its rotational drive in the ωZ direction. It is also possible, by using this aberration adjustment member 21, to control the rotationally asymmetric difference between longitudinal and lateral magnifications having twofold symmetry with regard to an arbitrary direction, and perform exposure in the same manner as in Example 1.

As explained above, the main control unit 103 in Examples 1 to 3 controls a direction of an aberration having twofold symmetry determined in accordance with a position in two degrees of freedom of the optical element having different powers in two directions by using the optical element driving unit 113 which drives the optical element with at least two degrees of freedom.

### Second Embodiment

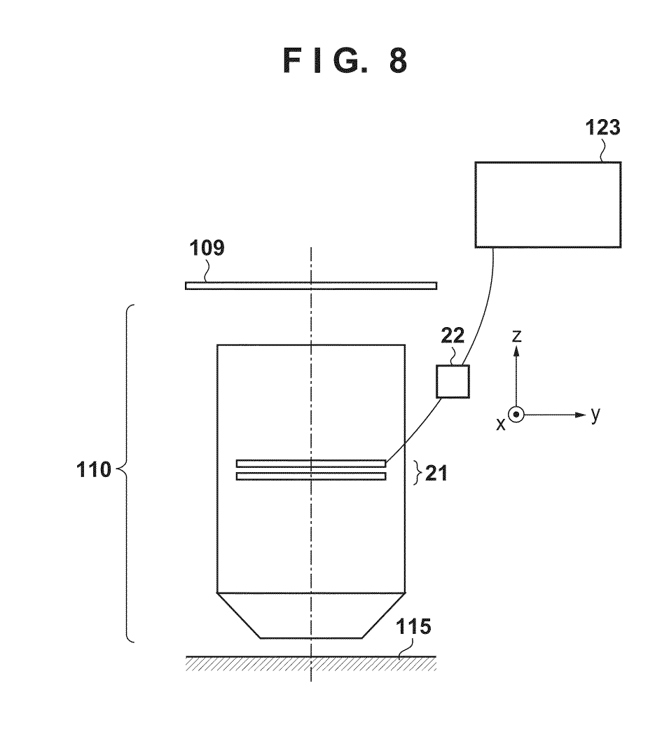

FIG. 8 is a diagram showing a projection optical system including an adjustment mechanism according to the second embodiment. A projection optical system 110 in this embodiment is an optical system of a refractive type, a catadioptric system, or the like, and projects the pattern on a reticle 109 (mask) illuminated by an illumination system (not shown) on a wafer 115 (substrate). As shown in FIG. 8, the projection optical system 110 includes inside it an aberration adjustment member 21 for adjusting an aberration having twofold symmetry. The aberration adjustment member 21 has two optical elements (first optical element and second optical element) 211 and 212 with aspheric surfaces, and is configured, by an optical element control unit 123, so that at least one of the two optical elements is movable or rotatable.

As in the first embodiment, an astigmatism (AS) can be created and controlled with regard to an arbitrary direction by combining a drive of the optical element 211 with two degrees of freedom.

### Third Embodiment

A method of manufacturing a device (for example, a semiconductor device or a liquid crystal display device) according to the first embodiment of the present invention will now be described. A semiconductor device is manufactured by a preprocess of forming an integrated circuit on a wafer, and a post-process of completing, as a product, a chip of the integrated circuit formed on the wafer by the preprocess. The preprocess includes a step of performing a scan exposure for the wafer coated with a photosensitive agent using the above-described exposure apparatus, and a step of developing the wafer. The post-process includes an assembly step (dicing and bonding) and packaging step (encapsulation). A liquid crystal display device is manufactured by a step of forming a transparent electrode. The step of forming a transparent electrode includes a step of coating with a photosensitive agent a glass substrate on which a transparent conductive film is deposited, a step of performing a scan exposure for the glass substrate coated with the photosensitive agent using the above-described exposure apparatus, and a step of developing the glass substrate. The device manufacturing method according to the embodiment can manufacture higher-quality device than the prior arts.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-276121, filed Dec. 18, 2012, which is hereby incorporated by reference herein in its entirety.

1. An exposure apparatus of projecting a pattern of a reticle on a substrate via a projection optical system and exposing the substrate to light, the apparatus comprising:
an optical element positioned along an optical axis of the projection optical system and configured to include a surface having a rotationally asymmetric shape;
a driving unit configured to drive said optical element with at least two degrees of freedom; and
a control unit configured to control the drive with two degrees of freedom to correct an aberration having twofold symmetry in a direction represented by a linear sum of the aberration of components in two directions based on information showing a relationship between a driving amount with two degrees of freedom and the components of the aberration in the two directions, and an amount to be adjusted of each of the components of the aberration in the two directions.

2. The exposure apparatus according to claim 1, further comprising a measurement device configured to measure a shape of a plurality of shot regions as an underlayer of the substrate,
wherein said control unit obtains the amount to be adjusted for the respective components of the aberration in the two directions based on a distortion of the shape of the plurality of shot regions measured by said measurement device.

3. The exposure apparatus according to claim 1, wherein when a Z-axis is defined as a direction parallel to the optical axis, and an X-axis and a Y-axis are defined to be orthogonal to each other on a plane perpendicular to the optical axis, a surface of the rotationally asymmetric shape is represented by z=Ax³+B(x+y)³ (where A and B are constants), and the drive with two degrees of freedom includes a drive along a Y-axis direction and a drive along a direction forming an angle of 135° from the X-axis on an X-Y plane.

4. The exposure apparatus according to claim 1, wherein assuming that r and θ are variables, and A and B are constants, the surface of the rotationally asymmetric shape is represented by Ar³ cos 3θ or Br³ sin 3θ, and the drive with two degrees of freedom includes drives along two axes orthogonal to each other on the plane perpendicular to the optical axis.

5. The exposure apparatus according to claim 1, wherein when a direction parallel to the optical axis is defined as a Z-axis, and directions orthogonal to each other on a plane perpendicular to the optical axis are defined as an X-axis and a Y-axis, the surface of the rotationally asymmetric shape is a plane represented by a straight line with a projection on a Y-Z plane inclined with respect to the Y-axis, and the drive with two degrees of freedom includes rotational drives about the X-axis and about the Y-axis.

6. The exposure apparatus according to claim 1, wherein the surface of the rotationally asymmetric shape is represented by a cylindrical surface, or Ar² cos 2θ or Br² sin 2θ where r and θ are variables, and A and B are constants, the drive with two degrees of freedom includes a drive along the optical axis and a rotational drive about the optical axis.

7. The exposure apparatus according to claim 1, wherein the aberration having twofold symmetry is astigmatism or a magnification difference.

8. The exposure apparatus according to claim 1, wherein said optical element is positioned between a reticle stage for holding the reticle and the projection optical system.

9. The exposure apparatus according to claim 1, wherein said optical element is positioned within the projection optical system.

10. A method of manufacturing a device, the method comprising:
projecting a pattern of a reticle on a substrate via a projection optical system and exposing the substrate to light using an exposure apparatus;
developing the exposed substrate; and
processing the developed substrate to manufacture the device,
wherein the exposure apparatus includes:
an optical element positioned along an optical axis of the projection optical system and configured to include a surface having a rotationally asymmetric shape;
a driving unit configured to drive said optical element with at least two degrees of freedom; and
a control unit configured to control the drive with two degrees of freedom to correct an aberration having twofold symmetry in a direction represented by a linear sum of the aberration of components in two directions based on information showing a relationship between a driving amount with two degrees of freedom and the components of the aberration in the two directions, and an amount to be adjusted of each of the components of the aberration in the two directions.

11. An exposure method of projecting a pattern of a reticle on a substrate via a projection optical system and exposing the substrate to light using an exposure apparatus,
the exposure apparatus comprising:
an optical element positioned along an optical axis of the projection optical system and configured to include a surface having a rotationally asymmetric shape, which is; and
a driving unit configured to drive said optical element with at least two degrees of freedom,
the method comprising a step of controlling the drive with two degrees of freedom in order to control an aberration having twofold symmetry with regard to a direction according to distortion on a shape of a shot region on the substrate based on information showing a relationship between a driving amount with two degrees of freedom and the components of the aberration in the two directions, and an each amount to be adjusted of each of the components of the aberration in the two directions.

12. An exposure apparatus of projecting a pattern of an original on a substrate via an optical element and exposing the substrate to light, the apparatus comprising:
the optical element having different powers in two directions;
a driving unit configured to drive said optical element with at least two degrees of freedom; and
a control unit configured to control a direction of an aberration having twofold symmetry determined in accordance with a position in two degrees of freedom of said optical element.
